(19) United States
(12) Patent Application Publication
(10) Pub. No.: US 2003/0092236 A1
(43) Pub. Date: May 15, 2003

(54) Flash memory cell and method to achieve multiple bits per cell

(76) Inventors: Danny Shum, Poughkeepsie, NY (US); Georg Tempel, Sterrebeek (BE); C. Ludwig, Langenbrueck (DE)

Correspondence Address: Thomas R. FitzGerald, 16 E. Main Street, Suite 210, Rochester, NY, 14614-1803, US

(21) Appl. No.: 09/772,220

(22) Filed: Jan. 29, 2001

Related U.S. Application Data
(60) Provisional application No. 60/179,234, filed on Jan. 31, 2000.

(51) Int. Cl. H01L 21/336

(52) U.S. Cl. 438/257

(57) ABSTRACT

A method of flash memory cell programming is provided which uses a uniform electric potential across tunnel oxide. The tight Vt distribution and very stable Vt shift over program/erase cycling allows for a multi-level cell capable of having more than 2 bits per cell.

This application claims priority under 35 USC 119 (e) of a provisional application entitled “Flash Memory Cell and the Method to Achieve Multiple Bits Per Cell and One Transistor Flash Memory Cell and the Method of Recovery From Over-Erasure” Application No. 60/179,234 filed Jan. 31, 2000 by inventors Danny Shum, Georg Tempel, and G. C. Ludwig

### BACKGROUND OF THE INVENTION

Density is a major consideration in fabrication of semiconductor memories. Consequently the amount of semiconductor real estate used in storing a bit of information on a semiconductor chip is directly related to price. Process scaling techniques which utilize feature size reduction have been a primary mechanism to achieve high density in the past. Multi-Level Cell (MLC) technology has been used as a method to further increase cell density by increasing the number of possible states associated with a memory cell. MLC technology allows a memory cell to store information corresponding to more than one bit. Consequently, four states from a selection of 2^{N} states can be stored in each cell. Each state corresponds to a two-bit data pattern, 00, 01, 10 or 11.

U.S. Pat. No. 5,553,020, entitled “Structure and Method for Low Current Programming of Flash EEPROMS,” by Stephen N. Keeney and Gregory E. Atwood, and U.S. Pat. No. 5,515,317, entitled “Addressing Modes for a Dynamic Single Bit Per Cell to Multiple Bit Per Cell Memory,” by Steven E. Wells and Kurt B. Robinson are hereby incorporated by reference.

Flash memory cells have enjoyed recent commercial success due to their relatively low cost, the ease in erasing information stored in a flash memory array and their applications to bank check cards, credit cards, and the like. A flash memory cell which is recognized by the semiconductor industry as a standard has not yet emerged. Many types of flash memories exist which embody many different architectures. The programming, reading and erasing of cells can be generally described under one of the following architectures—NOR, AND, or NAND. Further, the programming mechanism of the flash memory cell typically involves Fowler-Nordheim tunneling through an energy barrier or electron injection over an energy barrier.

The array erase mechanism for Fowler-Nordheim cells can involve floating gate to channel, floating gate to drain or floating gate to source as the charge clearing path from the floating gate. The floating gate to drain or source path can prove deleterious to cell operation by destroying the tunnel oxide area located between the floating gate overlap and the drain/source region. On the other hand the tunnel oxide can also be destroyed through the programming mechanisms (e.g., programming a logic one or logic zero on the floating gate) of conventional Fowler-Nordheim flash cells. These programming mechanisms can include charge carrier paths between the floating gate and drain or alternatively between the floating gate and source. However, conventional cells do not include a programming operation involving a path between the channel and floating gate. Such an operation would be desirable from a standpoint of limiting tunnel oxide degradation due to the field re-distribution effect across the entire tunnel oxide region. Until now, a flash memory cell which allows uniform channel programming has not existed.

### BRIEF DESCRIPTION OF THE DRAWINGS

FIG. 1 illustrates a partial schematic/partial cross-sectional view of the flash memory cell according to the invention.

FIG. 2 illustrates a diagram/graph of increasing threshold voltage Vt versus an increasing number of program/erase cycles (#cycles).

FIG. 3 illustrates a diagram/graph of increasing threshold voltage Vt versus an increasing number of program/erase cycles for a one-transistor (1T) multi-level cell.

FIG. 4 is a block diagram which shows memory cell 48 connected to n (where n is a positive whole number) sense amplifiers 50 for determining the binary level (logic 0 or logic 1) of each associated state.

Reference numerals have been carried forward.

### DETAILED DESCRIPTION OF THE INVENTION

A flash memory which is programmed according to a method which uses a uniform electric potential across tunnel oxide has a number of advantages, particularly for multi-level cell applications. In order to explain this programming method a description of it follows with reference to a single level cell.

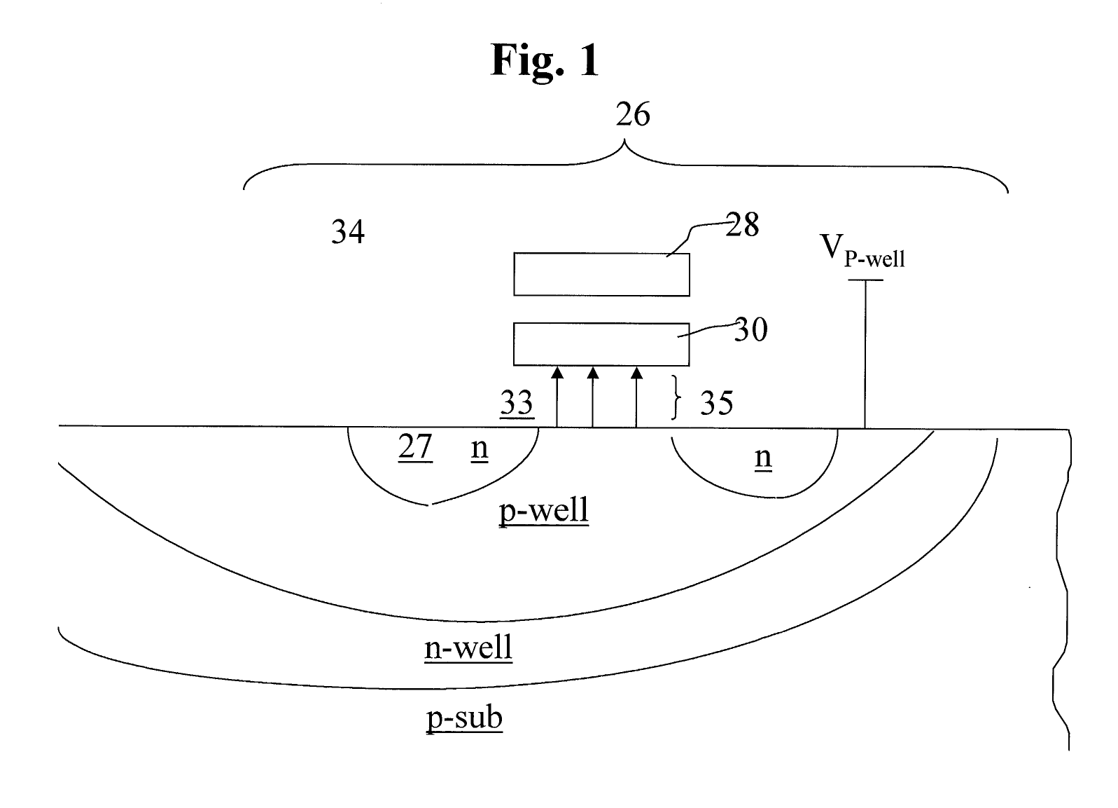

FIG. 1 illustrates a partial schematic/partial cross-sectional view of the flash memory cell according to the invention. This cell may be constructed according to fabrication methods combining triple well formation with dual gate technology. This triple-well comprises a first well region (labeled here as p-well), a second well region (labeled here as n-well) and a third well or substrate region (labeled here as p-sub). The conductivity type (e.g., n-type or p-type) will change according to the field-effect transistor being fabricated for the cell. The foregoing conductivity types correspond to n-channel devices. Opposite conductivity types to those named would be used with p-channel devices. Drain region 27 and source region 33 serve as the drain and source regions respectively for the floating gate structure generally indicated by reference number 26.

Programming:

To program a cell, such as cell 26, the associated bit line is toggled low (typically −3 volts) while the associated word line is toggled strongly high. Unselected cells sharing the same word line as the selected cell are subject to a phenomenon known as gate disturb, where the unselected cell could be unintentionally programmed. However, with the full voltage swing of opposite polarity between the selected bit line and unselected bit line make this situation less likely. A typical strong high voltage for the selected wordline for this application is around 12 to 13 volts. Selection gates (SG) for the memory array are held at a low level, typically −3 volts. Unselected bit lines remain at a high level, e.g around 3 to 4 volts. The bias of the p-well region, V_{P-well} for transistor 22 is held at a low voltage (e.g. −3 volts) while the source voltage V_{S} for the selection transistor 22 is left floating. Unselected cells which are associated with the bit line of a selected cell, such as BL₀ of cell 26 are subject to a phenomenon known as drain disturb wherein one of these unselected cells is programmed. However, the strong program voltage (i.e. 12 volts) generally required for programming makes this situation less likely. In connection with programming, a depletion mode transistor is turned off (programmed off or made to store a logic low level voltage) by carriers which (with reference to FIG. 1) tunnel in the direction of arrows 35 through a Fowler-Nordheim mechanism to floating gate 30. Note that tunneling through gate oxide 33 occurs from the channel region to the floating gate, rather than from a drain or source region to the floating gate. This particular tunnel mechanism helps prevent the destruction of the tunnel oxide as discussed in the foregoing section concerning prior art devices. The foregoing voltage characterizations apply to n-channel transistors. Opposite voltage levels (e.g. low instead of high, etc.) apply to p-channel transistors.

Erasing:

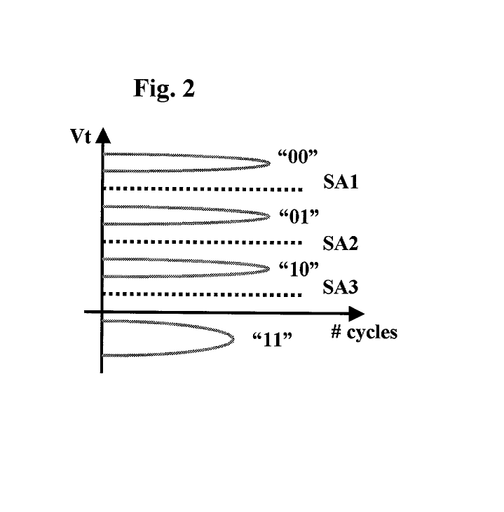

With reference to FIGS. 1 and 2, to erase a cell, such as cell 26, the associated bit line is left high (e.g. 3 volts) as is V_{S}, the source bias voltage of selection transistor 22. Gate 34 of selection transistor 22 is toggled high (e.g. 3 volts over the circuit supply voltage) along with the bias of the p-well, V_{P-well}.(e.g. 3 volts). Control gates 28 of unselected cells are toggled low (the circuit supply voltage). Control gate 28 of the selected cell 26 is toggled to a strong low, level, e.g. around −12 to −14 volts. V_{P-well} is maintained at a high level (e.g. 3 volts). A phenomenon known as erase disturb wherein unselected cells are erased could occur. However, due the relatively strong negative voltage (e.g. −12 volts) used to erase a cell, this is less likely.

Reading:

With reference to FIG. 1, in order to read the contents of a selected memory cell 22, selection gate 34 of transistor 22 within cell 28 is toggled high (e.g., the circuit supply voltage) along with the associated bit line BL₀ (e.g. 1.5 volts) of selected cell 26. Unselected bit lines are biased low (e.g., circuit ground) Likewise voltage V_{P-well}, the p-well voltage is biased low (at circuit ground.) V_{S}. is also maintained low (i.e., circuit ground). Selection gate 34 of unselected bit lines are pulled low. Control gates 28 are pulled low (e.g., circuit ground) during a read operation. Bit line disturb could occur along cells associated with BL₀. Additionally gate disturb could occur along cells associated with cells having the same selection gate line as the selected cell. The use of the circuit supply voltage in the former case involving gate disturb and the low voltages used involving the latter case make these situations unlikely.

The chart below summarizes the foregoing described cell scenarios: Note that selection lines are operable to carry voltages capable of turning transistor 22 on or off, thus selecting a cell.

| | Transistor | Bit line BL₀ | V_{S} | V_{P} (well) | Control Gate | Selection Transistor |
|---|---|---|---|---|---|---|
| | State | (volts) | (volts) | (volts) | (volts) (28) | Gate (volts) (34) |
| PROGRAM | | | | | | |
| Selected Cell | Transistor 22- | −3 | floating | −3 | +12 to +13 | −3 |
| | off | | | | | |
| Non Selected | Transistor 22- | +3 to +4 | Floating | −3 | +12 to +13 | −3 |
| Cell | off | | | | | |
| (Possible- | | | | | | |
| unlikely gate | | | | | | |
| disturb) | | | | | | |
| Non Selected | Transistor 22- | −3 | Floating | −3 | 0 to −3 | −3 |
| Cell | off | | | | | |
| (Possible- | | | | | | |
| unlikely | | | | | | |
| bitline disturb) | | | | | | |
| ERASE | | | | | | |
| Selected Cell | Transistor 22- | +3 | +3 | +3 | −12 to −14 | Supply voltage +3 |
| | on | | | | | |
| Non Selected | Transistor 22- | +3 | +3 | +3 | 0 to +3 | Supply voltage +3 |
| Cell | on | | | | | |
| (Possible- | | | | | | |
| unlikely gate | | | | | | |
| disturb) | | | | | | |
| READ | | | | | | |
| Selected Cell | Transistor 22- | +1.5 | 0 | 0 | 0 | Circuit supply |
| | on | | | | | |
| Non Selected | Transistor 24- | 0 | 0 | 0 | 0 | Circuit supply |
| Cell | off | | | | | |
| (Possible- | | | | | | |
| unlikely gate | | | | | | |
| disturb) | | | | | | |
| Non Selected | Transistor 22- | +1.5 | 0 | 0 | 0 | 0 |
| Cell | off | | | | | |
| (Possible- | | | | | | |
| unlikely | | | | | | |
| bitline disturb | | | | | | |

Benefits of the Well:

A primary advantage of the invention is provided by the triple well structure. In view of the 70% cell coupling, which is typical in this art, the forgoing described programming biasing scheme involving 12 to 13 volts on the control gate and −3 volts on the p-well (V_{P}=−3 volts) results in approximately 11 volts across a 100 Å tunnel oxide 33 as shown in FIG. 1. A structure with 12 volts on the control gate but without the negatively biased substrate (e.g., a substrate voltage of 0 volts at region 33) (e.g., a non-triple well structure) would only develop 8.4 volts across tunnel oxide 33 of FIG. 1. It has been shown, and is well known, that electron tunneling is an extremely sensitive function of the capacitor cathode electric field and that electron tunneling requires a cathode electric field, Eₖ=Vₜₓ/Tₜₓ, of at least 10⁷ V/cm (where Tₜₓ is the tunnel dielectric thickness and Vₜₓ is the voltage dropped across this dielectric thickness, e.g. tunnel oxide 33). 11 volts across 100 Å tunnel oxide 33 of FIG. 1 provides an Eₖ=1.1*10⁷ V/cm. By contrast, an 8.4 voltage across the tunnel oxide for a non-triple well structure in the example above, provides an Eₖ=0.84*10⁷ V/cm. Consequently, this Eₖ is in sufficient to cause tunneling, thusly, herein lies an advantage of the triple well structure.

Another primary benefit of the triple well structure is that it allows scaling of the memory cell. Decreases in the size of the cell can include an attendant decrease in bias voltages, independent of the supply voltage. Structures without a triple well are penalized in that scaling is limited by the supply voltage since some minimum supply voltage will be required for proper functioning of peripheral circuitry, e.g. sense amps, etc. The foregoing triple well benefits are in addition to the beneficial effects of the tunnel mechanism which prevents destruction of the tunnel oxide as previously mentioned.

When the above concept of programming is applied to a multi-level cell (MLC), a high density memory array can be achieved using the same generation of technology. Conventional methods to achieve MLC relies primarily on injection programming such as source-side hot-electron programming. However, this method of programming is not suitable for low power portable applications, e.g. cell phones, etc. Conventional low power methods of tunneling result in wide Vt (threshold voltage) distribution and Vt shift over time due to hole trapping. This can result in a large internal read voltage to compensate for the wide Vt window which in turn may cause data retention problems. The programming method according to the invention uses a uniform electric potential across the tunnel oxide. With reference to FIG. 1, this electric potential extends between the p-well and the control gate 28. A constant field on the memory array is achieved by this method of programming. The main advantages are a tight Vt distribution and very stable Vt shift over program/erase cycling. For instance, experimental results indicate a shift of only about 100 mV after 100 k program/erase cycles. This programming method also allows a multi-level cell with more than two bits per cell.

FIG. 2 illustrates a diagram/graph of increasing threshold voltage Vt versus an increasing number of program/erase cycles (#cycles). SA indicates sense amplifier. One sense amp (SA) is indicated for each threshold voltage distribution. Binary number 00 through 11 indicate a multilevel cell with 2ⁿ states with n bits. For that shown in FIG. 2, n is equal to 2. FIG. 2 is further directed to a two transistor (2T) memory cell. As shown, one state (which is shown for instance as 11) is associated with a negative threshold voltage. A medium, but boosted, internal voltage for read operations is sufficient for a read operation for the 2T cell. Thusly, with reference to FIG. 1, a boosted value of for instance 4.5 volts is applied to selection gate 34.

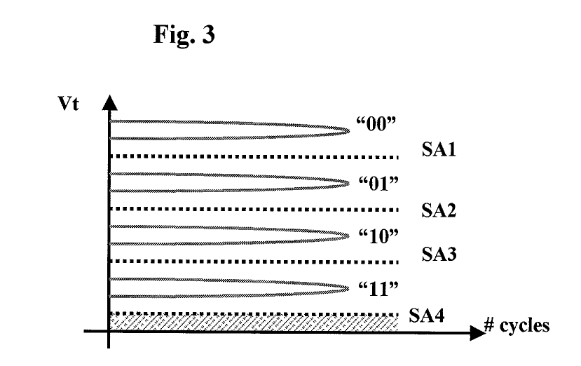

FIG. 3 illustrates a diagram/graph of increasing threshold voltage Vt versus an increasing number of program/erase cycles for a one transistor (1T) multi-level cell. A higher wordline boosting is required for read operations with this cell as compared with the 2T case discussed above. A sufficient boosted value is for instance, 6 volts. The data retention after cycling is not as good as the 2T case due to higher internal read voltage.

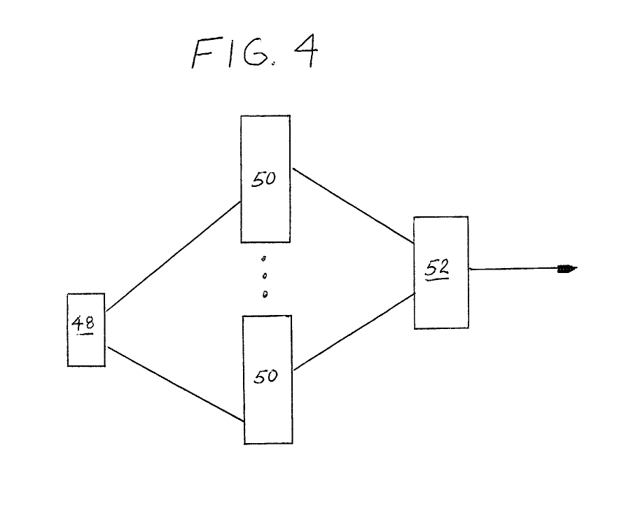

FIG. 4 is a block diagram which shows memory cell 48 connected to n (where n is a positive whole number) sense amplifiers 50 for determining the binary level (logic 0 or logic 1) of each associated state. There are n sense amps for each state. Consequently, a multi-level cell capable of storing 2ⁿ states will have n sense amplifiers. Each sense amplifier being capable of distinguishing a given binary level within a range of voltages along a given Vt distribution as shown in FIGS. 2 and 3. Sense amplifiers 50 are connected to logic circuitry 52 which outputs a multiplexed result corresponding to the level stored in memory cell 48. Memory cell 48 can comprise a 1T or 2T memory cell.

Although the invention has been described in detail herein with reference to preferred embodiments and certain described alternatives, it is to be understood that this description is by way of example only, and it is not to be construed in a limiting sense. It is to be further understood that numerous changes in the details of the embodiments of the invention and additional embodiments of the invention, will be apparent to, and may be made by, persons of ordinary skiff in the art having reference to this description. It is contemplated that all such changes and additional embodiments are within the spirit and true scope of the invention as claimed below.

We claim:

1. A flash memory comprising:
a plurality of multi-level cells, each said cell including a floating gate, a channel and tunnel oxide wherein each said cell is capable of being programmed according to a method of using a substantially uniform electric potential which lies substantially between said tunnel oxide and said floating gate.

2. A flash memory cell as recited in claim 1 wherein each said multi-level cell is a one transistor memory cell.

3. A flash memory cell as recited in claim 2 wherein each said multi-level cell is a two transistor memory cell.

4. A flash memory cell as recited in claim 1 wherein each multi-level cell is capable of storing 2ⁿ states where n is a whole number which is greater than or equal to two.
